(19) United States
(12) Patent Application Publication
(10) Pub. No.: US 2006/0065523 A1
(43) Pub. Date: Mar. 30, 2006

(54) Corrosion resistant apparatus for control of a multi-zone nozzle in a plasma processing system

(76) Inventors: Fangli Hao, Cupertino, CA (US); John Daugherty, Newark, CA (US); James Tappan, Fremont, CA (US)

Correspondence Address: IPSG, P.C., P.O. BOX 700640, SAN JOSE, CA, 95170-0640, US

(21) Appl. No.: 10/957,443

(22) Filed: Sep. 30, 2004

(51) Int. Cl. C23C 14/00; C23C 14/32

(52) U.S. Cl. 204/298.07; 204/192.12

(57) ABSTRACT

In a plasma processing system, an integrated gas flow control assembly for connecting a gas distribution system to a multi-zone injector is disclosed. The assembly includes a first set of channels connecting the gas distribution system to a first valve assembly with a first flow rate, a second valve assembly with a second flow rate, a third flow assembly with a third flow rate, and a fourth flow assembly with a fourth flow rate, wherein when the first valve assembly is substantially open, the third flow rate is less than the first flow rate, and wherein when the second valve assembly is substantially open, the fourth flow rate is less than the second flow rate. The assembly also includes a second set of channels for connecting the third flow assembly and the first valve assembly to a first multi-zone injector zone. The assembly further includes a third set of channels for connecting the fourth flow assembly and the second valve assembly to a second multi-zone injector zone. Wherein if the first valve assembly is closed, a first multi-zone injector zone flow rate is about the third flow rate, and wherein if the second valve assembly is closed, a second multi-zone injector zone flow rate is about the fourth flow rate.

### BACKGROUND OF THE INVENTION

The present invention relates in general to substrate manufacturing technologies and in particular to a corrosion resistant apparatus for control of a multi-zone nozzle in a plasma processing system.

In the processing of a substrate, e.g., a semiconductor substrate or a glass panel such as one used in flat panel display manufacturing, plasma is often employed. As part of the processing of a substrate for example, the substrate is divided into a plurality of dies, or rectangular areas, each of which will become an integrated circuit. The substrate is then processed in a series of steps in which materials are selectively removed (etching) and deposited (deposition) in order to form electrical components thereon.

In an exemplary plasma process, a substrate is coated with a thin film of hardened emulsion (i.e., such as a photoresist mask) prior to etching. Areas of the hardened emulsion are then selectively removed, causing components of the underlying layer to become exposed. The substrate is then placed in a plasma processing chamber on a substrate support structure comprising a mono-polar or bi-polar electrode, called a chuck or pedestal. Appropriate etchant source is then flowed into the chamber and struck to form a plasma to etch exposed areas of the substrate.

Referring now to FIG. 1, a simplified diagram of a capacitive coupled plasma processing system is shown. In a common configuration, the plasma chamber is comprised of a bottom piece 150 located in the lower chamber, and a detachable top piece 152 located in the upper chamber. A first RF generator 134 generates the plasma as well as controls the plasma density, while a second RF generator 138 generates bias RF, commonly used to control the DC bias and the ion bombardment energy.

Further coupled to source RF generator 134 is matching network 136a, and to bias RF generator 138 is matching network 136b, that attempt to match the impedances of the RF power sources to that of plasma 110. Furthermore, pump 111 is commonly used to evacuate the ambient atmosphere from plasma chamber 102 in order to achieve the required pressure to sustain plasma 110.

Generally, an appropriate set of gases, such as halogens (i.e., hydrogen chloride, hydrogen bromide, boron trichloride, chlorine, bromine, silicon tetrachloride, etc.), is flowed into chamber 102 from gas distribution system 122 to shut off valve 123 located in the lower chamber. Since injector 109 may comprise different sets or zones of independently controlled nozzles (e.g., in order to optimize the substrate uniformity), it may be connected to a gas flow control assembly 125, located in the upper chamber, which is further coupled to shut off valve 123. In one example, the zones on a multi-zone injector comprise a center set of nozzles principally introducing plasma gases into the center of the plasma, and an edge set of nozzles principally injecting plasma gases into the remaining part of the plasma.

Typically, gas flow control assembly 125, comprising a series of stainless steel conduits, valves, bypasses, and flow restrictions, provides the necessary gas flow adjustments at injector 109. These plasma gases may be subsequently ionized to form a plasma 110, in order to process (e.g., etch or deposition) exposed areas of substrate 114, such as a semiconductor substrate or a glass pane, positioned with edge ring 115 on an electrostatic chuck 116, which also serves as an electrode.

In a common substrate manufacturing method known as polysilicon gate etching, a conductive polysilicon layer is patterned with photoresist and then etched to form the gate of a field-effect transistor. In this method, typical etching gases include chlorine, hydrogen bromide, hydrogen chloride, and oxygen.

In general, the yield and reliability of semiconductor devices are functions of contamination in all stages of fabrication. In particular, the degree of contamination is usually dependent on the specific plasma process (e.g., chemistry, power, and temperature) and the initial surface condition of the plasma chamber. Metal contamination in particular is very problematic, since metal tends to rapidly diffuse into the substrate. Metal contamination levels are usually specified by customers at about <5×10¹⁰ atoms cm⁻² (except for aluminum which has a specification of about <1×10¹¹ atoms cm⁻²). This target generally represents a metal contamination level of about 1 in 20,000 atoms on the substrate.

For example, a metal can act as a dopant if it reaches a transistor gate on the substrate, potentially shifting the gate electrical characteristics. In addition, metals can add to leakage currents and cause reliability problems.

A potential source of metal contamination is electropolished stainless steel used in the gas flow control assembly. Stainless steel is often chosen because it is a non-porous material commonly made of iron (Fe), with significant alloying additions of chromium (Cr), which gives the metal its “stainless” or corrosion-resistant characteristics, and nickel (Ni), which stabilizes the austenite, makes the metal nonmagnetic and tough, and also contributes to corrosion resistance.

Electropolishing generally improves the surface chemistry of the part, enhancing the “passive” oxide film and removing any free iron from the surface. Generally, when first exposed to oxygen, a passive film resisting further oxidation rapidly forms, subsequently creating a “passivated” metal.

However, repeated exposure to corrosive plasma processing gases (e.g., fluorine, chlorine, bromine, etc.) tends to attack the stainless steel. The degree of corrosion and hence the amount of contamination may depend on many factors, such as gas concentration and purity, moisture content, temperature, system flow rates, time of exposure, frequency of exposure. For instance, halogen gases, such as hydrogen chloride or hydrogen bromide, may corrode stainless steel when moisture levels exceed a few parts per billion (ppb).

Generally, when initially exposed to moisture, metal oxides tend to form hydrates and hydroxides which have thermodynamically strong (and hence inert) bonds. In the presence of a halogenated gas, however, these hydrates and hydroxides are no longer inert, and tend to form non-volatile metal compounds that can subsequently contaminate the substrate surface. In addition, conduit junctions that may be created by welds, as well as other heat-affected zones in the stainless steel conduit, undergo severe corrosion when halogen-based gases are transported. That is, the greater the number of weld junctions, the greater likelihood of corrosion and the greater the subsequent contamination of the substrate with corrosion byproducts.

Although moisture can be reduced, it generally cannot be completely eliminated. For example, although plasma processing gases are normally stored in a purified form in compressed gas cylinders, moisture can be introduced into the gas distribution system when the cylinders are replaced, or when maintenance is performed on the processing chamber.

Another source of potential contamination may be the byproducts formed by the process of joining pieces of stainless steel together, such as non-welded and welded bonds. Non-welded bonds are generally formed by gasketed seals, brazing, or soldering at high temperatures, while welded bonds are formed by heating the stainless steel to its melting point, and filler metal, if used, is fed into the molten pool.

However, the process of welding stainless steel often creates slag and layer re-deposits at the weld joints, potentially allowing corrosion. For example, materials such as sulfur (S), manganese (Mn), silicon (Si), and aluminum (Al) may be present at the weld site and tend to react with corrosive plasma processing gases, such as halogen, to produce corrosion and contaminants.

One solution is to minimize the surface area of the stainless steel conduit that can be potentially exposed to moisture, for example by reducing its length. However, this solution may be problematic for multi-zone injectors which require relatively complex valve, bypass, and flow restriction assemblies that are connected by varying conduit lengths.

In view of the foregoing, there are desired a corrosion resistant apparatus for control of a multi-zone nozzle in a plasma processing system.

### SUMMARY OF THE INVENTION

The invention relates, in one embodiment, in a plasma processing system, to an integrated gas flow control assembly for connecting a gas distribution system to a multi-zone injector. The assembly includes a first set of channels connecting the gas distribution system to a first valve assembly with a first flow rate, a second valve assembly with a second flow rate, a third flow assembly with a third flow rate, and a fourth flow assembly with a fourth flow rate, wherein when the first valve assembly is substantially open, the third flow rate is less than the first flow rate, and wherein when the second valve assembly is substantially open, the fourth flow rate is less than the second flow rate. The assembly also includes a second set of channels for connecting the third flow assembly and the first valve assembly to a first multi-zone injector zone. The assembly further includes a third set of channels for connecting the fourth flow assembly and the second valve assembly to a second multi-zone injector zone. Wherein if the first valve assembly is closed, a first multi-zone injector zone flow rate is about the third flow rate, and wherein if the second valve assembly is closed, a second multi-zone injector zone flow rate is about the fourth flow rate.

These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 shows a simplified diagram of an inductively coupled plasma processing system;

FIG. 2 shows a simplified diagram of a gas flow control assembly for a multi-zone injector;

FIG. 3 shows a simplified diagram of an integrated gas flow control assembly, according to one embodiment of the invention;

FIG. 4 shows a simplified diagram of an enhanced integrated gas flow control assembly including a valve sub-assembly and a flow restriction sub-assembly, according to one embodiment of the invention; and

FIG. 5 shows a simplified diagram of an inductively coupled plasma processing system with an integrated gas flow control, according to one embodiment of the invention.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

While not wishing to be bound by theory, it is believed by the inventor herein that an integrated gas flow control assembly can be created by connecting the valve, bypass, and flow restriction functions in a series of channels or cavities within a single assembly.

In one embodiment, a single block of material, such as Dupont Vespel or Hastelloy, can be machined (or manufactured in another appropriate manner) in order to accommodate the attachment of valves and the positioning of channels.

In another embodiment, a first sub-assembly comprising a block of material can be machined (or manufactured in another appropriate manner) in order to accommodate the attachment of valves, while a second sub-assembly comprising a block can be machined (or manufactured in another appropriate manner) to provide a substantial portion of the bypass and flow restriction functionality, wherein the first sub-assembly and the second sub-assembly are coupled to each other.

In another embodiment, a variable flow valve assembly is used. In another embodiment, a non-variable flow valve assembly is used. A valve assembly commonly comprises the valve and any additional attachment apparatus for coupling the assembly to the integrated gas flow control assembly.

In another embodiment, the injector can have any number of zones. Zones relate to sets of independently controlled injector nozzles that may be used in order to optimize the uniformity of the substrate. A common injector configuration comprises two zones: a first center set of nozzles principally introducing plasma gases into the center of the plasma, and a second edge set of nozzles principally injecting plasma gases into the remaining part of the plasma.

In another embodiment, an apparatus other than an injector may be used for introducing the plasma gas into a plasma chamber, such as a shower head.

In addition, since a single assembly may also reduce the total amount of stainless steel conduits and required conduit welds, a substantial portion of the potential metal contamination may be eliminated. Furthermore, the assembly may be located in the lower chamber and constructed from a material that is substantially transparent to the generated RF field.

For example, a first set of channels can be machined in an integrated gas flow control assembly connecting the gas distribution system to a first valve assembly with a first flow rate. A second set of channels can also be machined connecting the gas distribution system to a second valve assembly with a second flow rate.

A third set of channels can be machined connecting the gas distribution system to a third flow assembly with a third flow rate, and a fourth set of channels can be machined connecting the gas distribution system to a fourth flow assembly with a fourth flow rate. A flow assembly may comprise a set of channels that connect to other components or assemblies in the integrated gas flow assembly.

Wherein when the first valve assembly is substantially open, the third flow rate is less than the first flow rate, and wherein when the second valve assembly is substantially open, the fourth flow rate is less than the second flow rate.

A second set of channels can then be machined connecting the third flow assembly and the first valve assembly to a first multi-zone injector zone. A third set of channels can be machined connecting the fourth flow assembly and the second valve assembly to a second multi-zone injector zone. Wherein if the first valve assembly is closed, a first multi-zone injector zone flow rate is about the third flow rate, and wherein if the second valve assembly is closed, a second multi-zone injector zone flow rate is about the fourth flow rate.

However, if a valve assembly is opened, the flow to the corresponding injector zone may also be increased in proportion to the degree that a valve assembly is opened. If the valve assembly is a variable flow valve assembly, then the flow may be adjusted between a range that includes the restricted flow rate and an un-restricted flow rate. If the valve assembly is a non-variable flow valve assembly, then the selected flow may generally only be a restricted flow rate or an un-restricted flow rate.

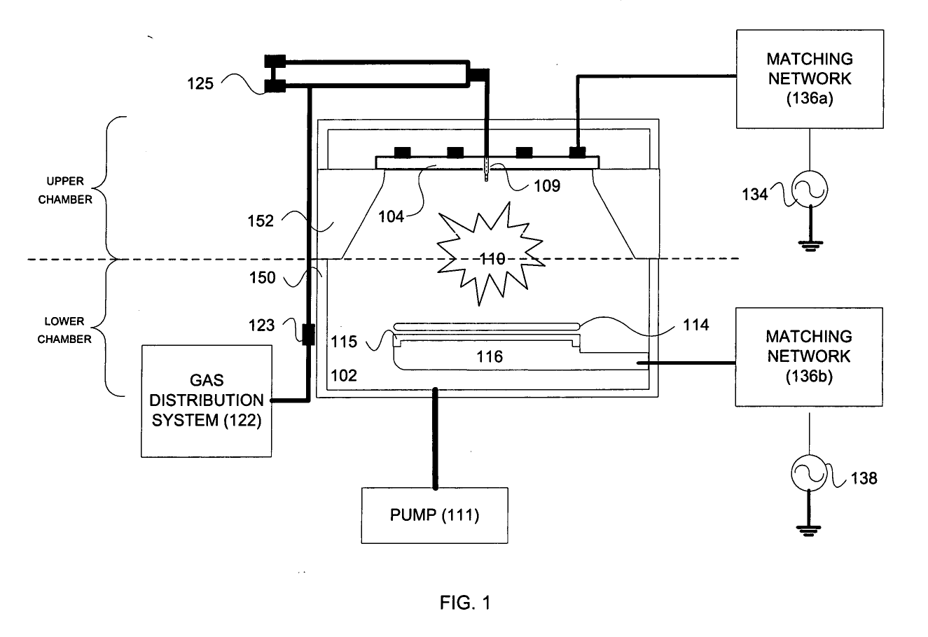

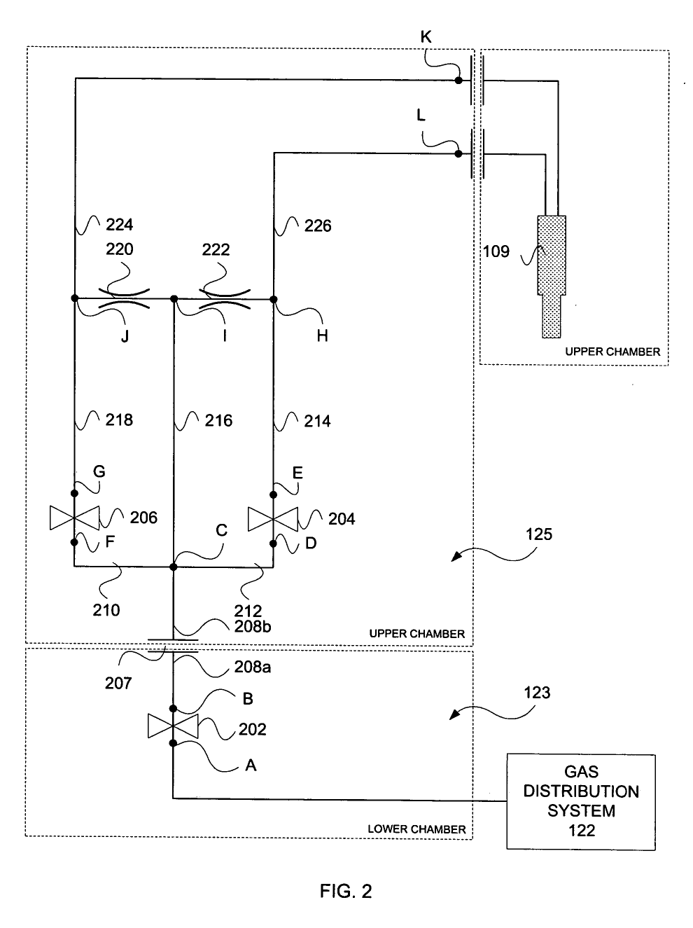

Referring now to FIG. 2, a simplified diagram of a gas flow control assembly 125 for a multi-zone injector in a plasma processing system is shown. In this diagram, injector 109, as shown in FIG. 1 is a dual zone plasma injector.

However, in order to both deliver and control the plasma gases, gas flow control assembly 125 tends to be asymmetrically constructed from varying lengths of conduits, valves, and bypasses. Since a substantial majority of the plasma gas delivery system is located in the upper chamber, the system's presence also tends to distort the electric field produced by the inductive antenna or capacitive electrode. In general, a conductive metal, such as stainless steal, will function as an antenna and hence will tend to absorb energy in an electromagnetic field. Subsequently, plasma gas delivery system tends distort an RF field, which may result in a substantially non-uniform plasma density across the substrate, and thus will potentially affect yield.

Generally, an appropriate set of gases, such as halogens (i.e., hydrogen chloride, hydrogen bromide, boron trichloride, chlorine, bromine, silicon tetrachloride, etc.), is flowed into a plasma chamber (not shown) from gas distribution system 122 through gas flow control assembly 125 to injector 109 located in an inlet in a top piece (not shown). Injector 109 may itself be comprised of a set of independently controlled nozzles, a first set in a center zone and a second set in a perimeter or edge zone. These plasma processing gases may be subsequently ionized to form a plasma (not shown), in order to process exposed areas of a substrate (not shown).

Gas distribution system 122 is generally coupled at junction A to main shut off valve 202 located in the lower chamber, which is in turn, is coupled via junction B through conduit 208a to lower-to-upper chamber interface 207. This interface allows the top piece (located in the upper chamber) to be safely removed from the bottom piece (located in the lower chamber) for cleaning and maintenance without damaging the plasma gas delivery system itself.

Lower-to-upper chamber interface 207 is further coupled to junction C that forks between a conduit 216, a bypass conduit 210 coupled to edge control valve 206 at junction F, and a bypass conduit 212 coupled to center control valve 204 at junction D. Conduit 216 is further coupled at junction I to restricted flow conduit 220 and restricted flow conduit 222.

If variable flow valve 206 and variable flow valve 204 are both closed, the plasma gas flow to both zones of injector 109 will be substantially restricted. Opening one of the valves will tend to increase the plasma gas flow to the corresponding zone, whereas opening both of the valves will tend to substantially equalize the plasma gas flow between both zones.

Edge control valve 206 is coupled to variable flow conduit 218 at junction G, which is in turn coupled to previously mentioned restricted flow conduit 220 at junction J. Likewise, edge control valve 204 is coupled to variable flow conduit 214 at junction E, which is in turn coupled to previously mentioned restricted flow conduit 222 at junction H.

Edge conduit 224 is further coupled at junction K, to injector 109, while center conduit 226 is further coupled at junction L, to an injector 109, which feed into the plasma chamber (not shown).

For example, the dimensions of a set of conduits as used in FIG. 2, may be as follows:

| | | | Exposed Surface |
|---|---|---|---|
| Conduit | Length (inch) | Diameter | Area in² |
| 224 | 16 | .25 | 9.4 |
| 226 | 16 | .25 | 9.4 |
| 218 | 7 | .25 | 4.1 |
| 214 | 7 | .25 | 4.1 |
| 210 | 2 | .25 | 1.2 |
| 212 | 2 | .25 | 1.2 |
| 208 | 11 | .25 | 6.5 |
| 222 | 5.3 | .5 | 3.1 |
| 220 | 5.3 | .4 | 3.1 |
| 216 | 2 | .25 | 1.2 |

| | |
|---|---|
| TOTAL EXPOSED SURFACE | 43.3 |

That is, there may be over 43 in² of surface area in the gas flow control assembly that may be exposed to moisture. In addition, there may also be about 54 welds that are exposed to moisture.

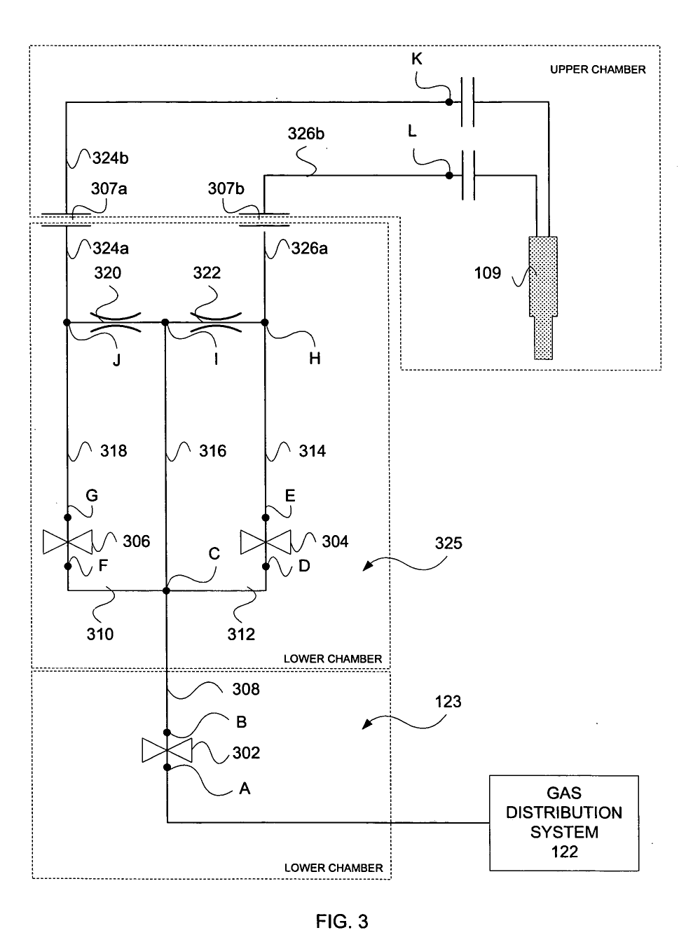

Referring now to FIG. 3, a simplified diagram of an integrated gas flow control assembly 325 for a multi-zone injector in a plasma processing system is shown, according to one embodiment of the invention. In a non-obvious way, by combining the valve, bypass, and flow restriction functions into a single integrated assembly, a substantial amount of stainless steel conduit of FIG. 2 has been eliminated, replaced with much shorter formed or machined channels. In addition, the integrated gas flow control assembly can also be located in the lower chamber, potentially reducing electromagnetic field distortion, and thus improving yield.

In this diagram, injector 109 as shown in FIG. 1 is a dual zone plasma injector. As preciously described, an appropriate set of gases such as halogens (i.e., tungsten hexafluoride, hydrogen bromide, etc.), is flowed into a plasma chamber (not shown) from gas distribution system 122 through integrated gas flow control assembly 325 to injector 109 located in an inlet in a top piece (not shown). Injector 109 may itself be comprised of a set of independently controlled nozzles, a first set in a center zone and a second set in a perimeter or edge zone. These plasma processing gases may be subsequently ionized to form a plasma (not shown), in order to process exposed areas of a substrate (not shown).

In one embodiment, each zone can have either a substantially unrestricted flow or a substantially restricted flow independent of the other zone. In another embodiment, each zone can have a continuous range of flow volumes from substantially unrestricted to substantially restricted. In another embodiment, any number of independently controlled zones may be used. These plasma processing gases may be subsequently ionized to form a plasma (not shown), in order to process exposed areas of a substrate (not shown). In another embodiment, integrated gas flow control assembly 325 is comprised of a corrosion resistant industrial synthetic material, such as Dupont Vespel. In another embodiment, integrated gas flow control assembly 325 is comprised of a corrosion resistant industrial metal, such as Hastelloy.

Gas distribution system 122 is generally coupled at junction A to main shut off valve 302, which at junction B is further coupled through conduit 308 to junction C that forks between a channel 316, a bypass channel 310 coupled to edge control valve 306 at junction F, and a bypass channel 312 coupled to center control valve 304 at junction D.

As before, if valve 306 and valve 304 are both closed, the plasma gas flow to both zones of injector 109 will be substantially restricted. Opening one of the valves will tend to increase the plasma gas flow to the corresponding zone, whereas opening both of the valves will tend to substantially equalize the plasma gas flow between both zones.

Edge control valve 306 is coupled to channel 318 at junction G, which is in turn coupled to previously mentioned restricted flow channel 320 at junction J. Likewise, edge control valve 304 is coupled to channel 314 at junction E, which is in turn coupled to previously mentioned restricted flow channel 322 at junction H.

A lower-to-upper chamber interface 307b is coupled to junction H via channel 326a, and a lower-to-upper chamber interface 307a is coupled to junction J via channel 324a. A previously stated, this interface allows the top piece (located in the upper chamber) to be safely removed from the bottom piece (located in the lower chamber) for cleaning and maintenance without damaging the plasma gas delivery system itself.

Edge conduit 324b couples lower-to-upper chamber interface 307a to injector 109 at junction K, while center conduit 326b couples lower-to-upper chamber interface 307b to injector 109 at junction L

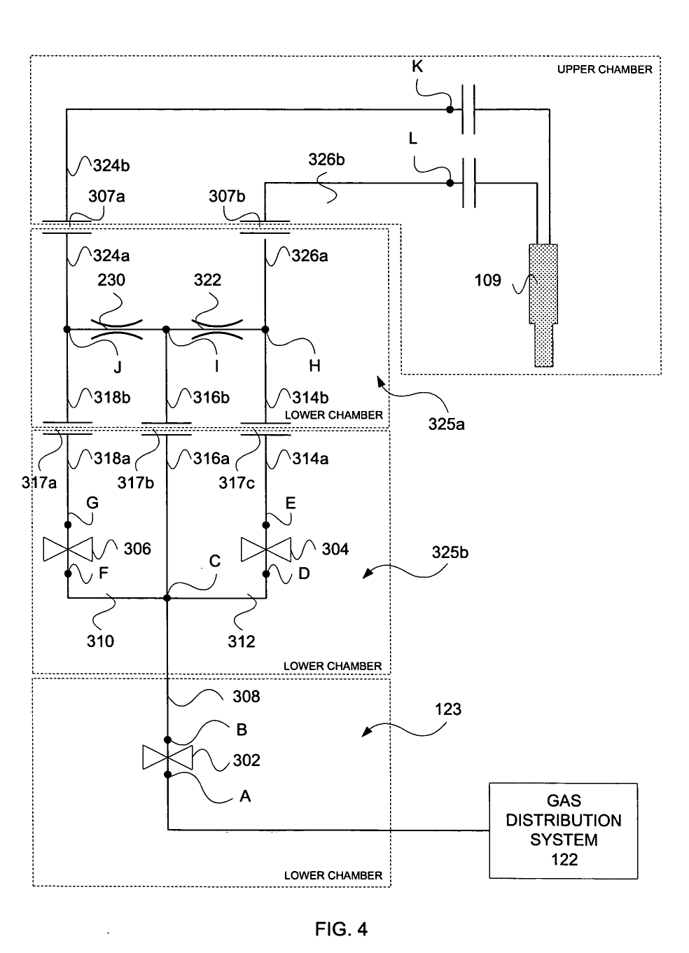

Referring now to FIG. 4, a simplified diagram of an enhanced integrated gas flow control assembly including a valve sub-assembly 325b and a flow restriction sub-assembly 325a is shown, according to one embodiment of the invention.

Gas distribution system 122 is generally coupled at junction A to main shut off valve 302, which at junction B is further coupled through conduit 308 to junction C that forks between a channel 316, a bypass channel 310 coupled to edge control valve 306 at junction F, and a bypass channel 312 coupled to center control valve 304 at junction D.

As before, if valve 306 and valve 304 are both closed, the plasma gas flow to both zones of injector 109 will be substantially restricted. Opening one of the valves will tend to increase the plasma gas flow to the corresponding zone, whereas opening both of the valves will tend to substantially equalize the plasma gas flow between both zones.

Edge control valve 306 is coupled to a sub-assembly interface 317a via channel 318a at junction G, which is in turn coupled to restricted flow channel 318b at junction J. Edge control valve 304 is coupled to a sub-assembly interface 317c via channel 314a at junction E, which is in turn coupled to restricted flow channel 314b at junction H. Sub-assembly interfaces 317a-c allow valve sub-assembly 325b and a flow restriction sub-assembly 325a to be uncoupled. For example, if a customer desires a more restricted gas flow, just the restriction sub-assembly 325a would need to be replaced.

A lower-to-upper chamber interface 307b is coupled to junction H via channel 326a, and a lower-to-upper chamber interface 307a is coupled to junction J via channel 324a. A previously stated, this interface allows the top piece (located in the upper chamber) to be safely removed from the bottom piece (located in the lower chamber) for cleaning and maintenance without damaging the plasma gas delivery system itself.

Edge conduit 324b couples lower-to-upper chamber interface 307a to injector 109 at junction K, while center conduit 326b couples lower-to-upper chamber interface 307b to injector 109 at junction L

For example, the dimensions of a set of channels and conduits as used in FIG. 3, may be as follows:

| Conduit/ | Length | | Exposed Surface |
|---|---|---|---|
| Channel | (inch) | Diameter | Area in² |
| 324 | 16 | .25 | 9.4 |
| 326 | 16 | .25 | 9.4 |
| 318 | 2 | .25 | 1.2 |
| 314 | 2 | .25 | 1.2 |
| 310 | .3 | .25 | .2 |
| 312 | .3 | .25 | .2 |
| 308 | 1 | .25 | .6 |
| 322 | 1.4 | .5 | .8 |
| 320 | 1.4 | .4 | .8 |
| 316 | .5 | .25 | .3 |

| | |
|---|---|
| TOTAL EXPOSED SURFACE | 24.1 |

That is, the total amount of exposed stainless steel has been reduced from 43 in² to about 24 in³, or about a 44% reduction of the surface area in the gas flow control assembly that may be exposed to moisture and the resulting contamination. In addition, in contrast to FIG. 2, there may be only about 20 welds which exposed to moisture, about a 63% reduction.

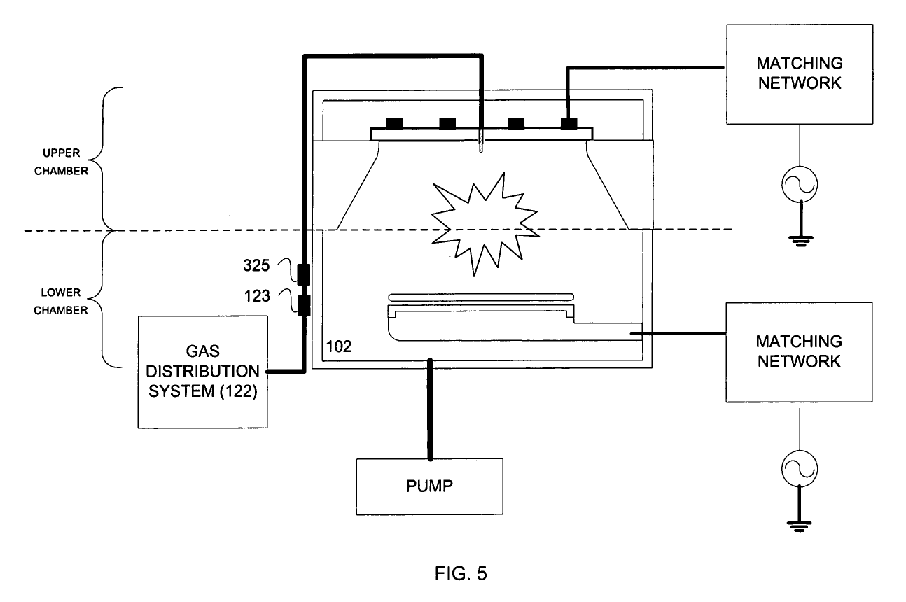

Referring now to FIG. 5, a simplified diagram of an inductively coupled plasma processing system with an integrated gas flow control assembly is shown, according to one embodiment of the invention.

Generally, an appropriate set of gases, such as halogens (i.e., hydrogen chloride, hydrogen bromide, boron trichloride, chlorine, bromine, silicon tetrachloride, etc.), is flowed into chamber 102 from gas distribution system 122 to shut off valve 123 located in the lower chamber. However, unlike FIG. 1, integrated gas flow control assembly 325 may be also located in the lower chamber.

While this invention has been described in terms of several preferred embodiments, there are alterations, permutations, and equivalents which fall within the scope of this invention. For example, although the present invention has been described in connection with Lam Research plasma processing systems (e.g., Exelan™, Exelan™ HP, Exelan™ HPT, 2300™, Versys™ Star, etc.), other plasma processing systems may be used (e.g., capacitively coupled, inductively coupled, atmospheric, deposition, etching, plasma treatment, plasma immersion ion implantation, etc.) This invention may also be used with substrates of various diameters (e.g., 200 mm, 300 mm, etc). It should also be noted that there are many alternative ways of implementing the methods of the present invention.

An advantage of the invention includes a corrosion resistant apparatus for control of a multi-zone nozzle in a plasma processing system. Additional advantages include the integration of valve, bypass, and flow restriction functions by a series of channels or cavities into a single assembly, the reduction of potential metal contamination, the reduction of surface area and welds, a better geometry that allows optimum surface finish and treatment, and the reduction of RF field interference.

Having disclosed exemplary embodiments and the best mode, modifications and variations may be made to the disclosed embodiments while remaining within the subject and spirit of the invention as defined by the following claims.

What is claimed is:

1. In a plasma processing system, an integrated gas flow control assembly for connecting a gas distribution system to a multi-zone injector, comprising:
a first set of channels connecting said gas distribution system to a first valve assembly with a first flow rate, a second valve assembly with a second flow rate, a third flow assembly with a third flow rate, and a fourth flow assembly with a fourth flow rate, wherein when said first valve assembly is substantially open, said third flow rate is less than said first flow rate, and wherein when said second valve assembly is substantially open, said fourth flow rate is less than said second flow rate;
a second set of channels for connecting said third flow assembly and said first valve assembly to a first multi-zone injector zone;
a third set of channels for connecting said fourth flow assembly and said second valve assembly to a second multi-zone injector zone;
wherein if said first valve assembly is closed, a first multi-zone injector zone flow rate is about said third flow rate, and wherein if said second valve assembly is closed, a second multi-zone injector zone flow rate is about said fourth flow rate.

2. The integrated gas flow control assembly of 1, wherein said first valve assembly and said second valve assembly each comprise a variable flow valve assembly.

3. The integrated gas flow control assembly of 1, wherein said first valve assembly and said second valve assembly each comprise a non-variable flow valve assembly

4. The integrated gas flow control assembly of 1, wherein said first valve assembly and said second valve assembly are located in a first sub-assembly of said integrated gas flow control assembly, and wherein said third flow assembly and said fourth flow assembly are substantially located in a second sub-assembly of said integrated gas flow control assembly.

5. The integrated gas flow control assembly of 1, wherein said integrated gas flow control assembly comprises ceramic.

6. The integrated gas flow control assembly of 1, wherein said integrated gas flow control assembly comprises plastic.

7. The integrated gas flow control assembly of 1, wherein said integrated gas flow control assembly comprises Dupont Vespel.

8. The integrated gas flow control assembly of 1, wherein said integrated gas flow control assembly comprises Hastelloy.

9. The integrated gas flow control assembly of 1, wherein said integrated gas flow control assembly comprises stainless steel.

10. The integrated gas flow control assembly of 1, wherein said integrated gas flow control assembly is located in a lower chamber of a plasma processing system.

11. The integrated gas flow control assembly of 1, wherein said integrated gas flow control assembly is substantially transparent to a RF field.

12. The integrated gas flow control assembly of 1, wherein said plasma processing system is a capactively coupled plasma processing system.

13. The integrated gas flow control assembly of 1, wherein said plasma processing system is an inductively coupled plasma processing system.

14. The integrated gas flow control assembly of 1, wherein said plasma processing system is an atmospheric plasma processing system.

15. In a plasma processing system, a plastic integrated gas flow control assembly that is substantially transparent to a RF field, for connecting a gas distribution system to a multi-zone injector, comprising:
a first set of channels connecting said gas distribution system to a first valve assembly with a first flow rate, a second valve assembly with a second flow rate, a third flow assembly with a third flow rate, and a fourth flow assembly with a fourth flow rate, wherein when said first valve assembly is substantially open, said third flow rate is less than said first flow rate, and wherein when said second valve assembly is substantially open, said fourth flow rate is less than said second flow rate;
a second set of channels for connecting said third flow assembly and said first valve assembly to a first multi-zone injector zone;
a third set of channels for connecting said fourth flow assembly and said second valve assembly to a second multi-zone injector zone;
wherein if said first valve assembly is closed, a first multi-zone injector zone flow rate is about said third flow rate, and wherein if said second valve assembly is closed, a second multi-zone injector zone flow rate is about said fourth flow rate.
